(19) United States
(12) Patent Application Publication
(10) Pub. No.: US 2009/0188552 A1
(43) Pub. Date: Jul. 30, 2009

(54) Nanowire-Based Photovoltaic Cells And Methods For Fabricating The Same

(76) Inventors: Shih-Yuan Wang, Palo Alto, CA (US); Michael Tan, Menlo Park, CA (US); Nobuhiko Kobayashi, Sunnyvale, CA (US); Denny Houng, Cupertino, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 12/243,740

(22) Filed: Oct. 1, 2008

Related U.S. Application Data
(60) Provisional application No. 61/063,156, filed on Jan. 30, 2008.

(51) Int. Cl. H01L 31/0352; H01L 31/18

(52) U.S. Cl. 136/255; 438/98; 257/E31.038

(57) ABSTRACT

Embodiments of the present invention relate to nanowire-based photovoltaic cells and to methods for fabricating the same. In one embodiment, a photovoltaic cell includes a first semiconductor layer doped with a first impurity and disposed on a portion of a first raised surface of a substrate and a second semiconductor layer doped with a second impurity and disposed on a second raised surface of the substrate. The first semiconductor layer has at least one negatively sloped surface, and the second semiconductor layer has at least one positively sloped surface neighboring the at least one negatively sloped surface of the first semiconductor layer. The photovoltaic cell includes at least one nanowire electronically coupled to the negatively sloped surface of the first semiconductor layer and electronically coupled to the positively sloped surface of the second semiconductor layer.

### CROSS-REFERENCE TO RELATED APPLICATION

The present application claims priority from provisional application Serial No. 61/063,156, filed Jan. 30, 2008, the contents of which are incorporated herein by reference in their entirety.

### TECHNICAL FIELD

Embodiments of the present invention relate to photovoltaic cells, and, in particular, to nanowire-based photovoltaic cells that include textured surfaces to improve nanowire connections.

### BACKGROUND

Photovoltaic cells are devices that convert light energy into electricity via a light-absorbing material. The electricity can flow through wires to power electronic devices. A solar cell is a type of photovoltaic cell configured to capture and convert sunlight into electricity. Assemblies of solar cells can be arrayed into modules, which, in turn, can be linked together into solar arrays. These arrays can be used to generate electricity in places where a power grid is not available, such as in remote area power systems, Earth-orbiting satellites and space probes, remote radio telephone, and water pumping systems. In recent years, due to the increased costs of generating electricity from fossil fuels, the demand for solar arrays that can be used to supplement home and commercial electrical power needs has increased.

However, most conventional photovoltaic cells only convert a small fraction of the light received into electricity. For example, efficiencies vary from about 6 to about 10% for amorphous silicon-based photovoltaic cells to about 43% for multiple junction-based photovoltaic cells. In addition, mass producing multiple junction photovoltaic cells that can be used to form photovoltaic arrays may be cost prohibitive. For example, the cost of mass producing a 30% efficient multiple junction photovoltaic cell may be as much as 100 times greater than the cost of producing an 8% efficient amorphous silicon-based cell. Thus, engineers and physicists have recognized a need for higher efficiency photovoltaic cells that can be mass produced.

### BRIEF DESCRIPTION OF THE DRAWINGS

FIG. 1A shows an isometric view of a p-n junction photovoltaic cell.

FIG. 1B shows an electronic energy-band diagram for the semiconductor layers of the photovoltaic cells shown in FIG. 1A.

FIG. 2A shows an isometric view of a first photovoltaic cell configured in accordance with embodiments of the present invention.

FIG. 2B shows an exploded isometric view of the first photovoltaic cell configured in accordance with embodiments of the present invention.

FIG. 3A shows a top view of the first photovoltaic cell configured in accordance with embodiments of the present invention.

FIG. 3B shows a cross-sectional view of the first photovoltaic cell along a line 3B-3B, shown in FIG. 3A, configured with a sinusoidal substrate in accordance with a first embodiment of the present invention.

FIG. 3C shows a cross-sectional view of the first photovoltaic cell along a line 3B-3B, shown in FIG. 3A, configured with a saw-tooth substrate in accordance with embodiment of the present invention.

FIG. 4A shows an exploded isometric view of a second photovoltaic cell configured in accordance with embodiments of the present invention.

FIG. 4B shows a cross-sectional view of the second photovoltaic cell along the 4B-4B, shown in FIG. 4A, configured with a sinusoidal substrate in accordance with a embodiment of the present invention.

FIG. 4C shows a cross-sectional view of the second photovoltaic cell along a line 4B-4B, shown in FIG. 4A, configured with a saw-tooth substrate in accordance with a second embodiment of the present invention.

FIGS. 5A-5B show cross-sectional views of reflective layers of the first and second photovoltaic cells configured in accordance with embodiments of the present invention.

FIG. 6A shows a top-view of a third photovoltaic cell configured in accordance with embodiments of the present invention.

FIG. 6B shows a top-view of a fourth photovoltaic cell configured in accordance with embodiments of the present invention.

FIG. 7 shows combining photovoltaic cells to produce a photovoltaic panel in accordance with embodiments of the present invention.

FIGS. 8A-8J show cross-sectional views of steps comprising a method for fabricating the photovoltaic cells, shown in FIG. 4, in accordance with embodiments of the present invention.

### DETAILED DESCRIPTION

Embodiments of the present invention relate to nanowire-based photovoltaic cells and to methods for fabricating the same. The photovoltaic cell embodiments of the present invention offer improved efficiency over conventional photovoltaic cells, and fabrication methods of the present invention can be used to mass produce photovoltaic cell embodiments. The term “light” as used to described various embodiments of the present invention is not limited to electromagnetic radiation with wavelengths that lie in the visible portion of the electromagnetic spectrum but also refers to electromagnetic radiation with wavelengths outside the visible portion, such as the infrared and ultraviolet portions, and can be used to refer to both classical and quantum (i.e., photons) electromagnetic radiation. In order to assist readers in understanding descriptions of various embodiments of the present invention, an overview subsection of photovoltaic cells is provided in a first subsection followed by a detailed description of embodiments of the present invention in a second subsection. In the various embodiments described below, a number of structurally similar components have been provided with the same reference numerals and, in the interest of brevity, an explanation of their structure and function is not repeated.

### Photovoltaic Cells

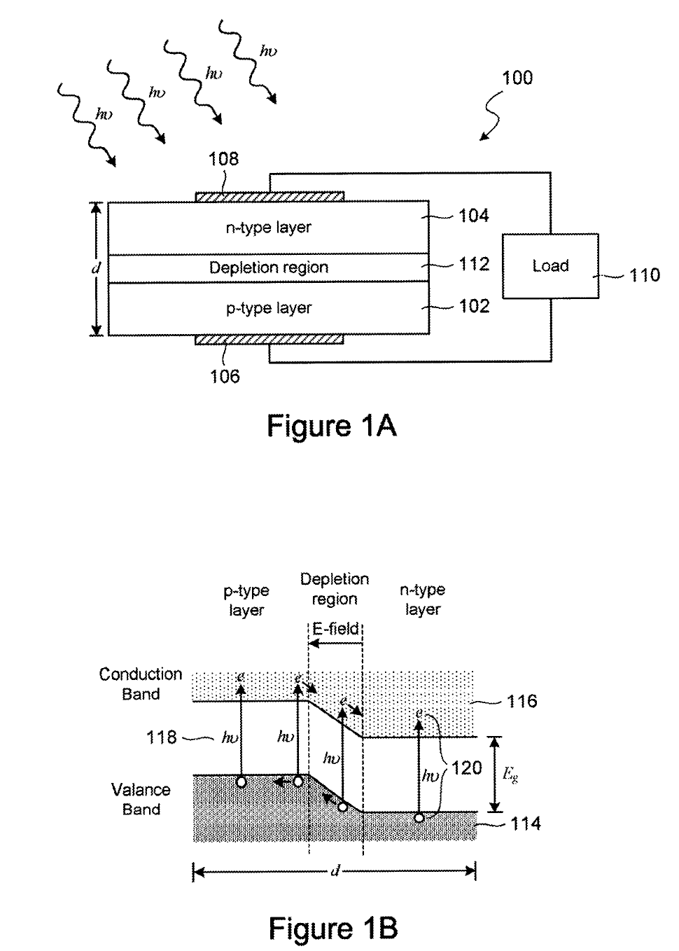

FIG. 1A shows a schematic representation of a p-n junction photovoltaic cell 100. The cell 100 comprises a p-type semiconductor layer 102 and an n-type semiconductor layer 106. The p-type layer 102 is disposed on a bottom electrode 106, and a top electrode 108 is disposed on the n-type layer 104. The electrodes 106 and 108 are connected to a load 110, such as an electronically opterated device. The p-type layer 102 is doped with an electron accepting impurity having fewer electrons than surrounding atoms in the semiconductor lattice creating vacant electronic energy states that can be characterizes as positively charged holes. On the other hand, the n-type layer 104 is doped with electron donating impurities that donate electrons to the semiconductor lattice. The electrons and holes are called “charge carriers.” A depletion region 112 forms between the p-type layer 102 and the n-type layer 104 as a result of electrons diffusing from the n-type layer 104 into the p-type layer 102. The potential difference across the depletion region 112 creates an electric field directed from the interface between the depletion region 112 and the n-type layer 104 to the interface between the deplection layer 112 and the p-type layer 102. This electric field forces electrons in the depletion region 112 to drift into the n-type layer 104. Ultimately, an equilibrium is reached where the number of electrons diffusing from the the n-type layer 104 into the depletion region 112 equals the number of electrons drifting from the depletion region 112 into the n-type layer 104.

FIG. 1B shows an electronic energy-band diagram for the layers 102, 104, and 112. Heavily shaded layers, such as layer 114, represent a continuum of mostly filled electronic energy states in the valance band, lightly shaded layers, such as layer 116, represent a continuum of mostly empty electronic energy states in the conduction band, and unshaded layers, such as layer 118, represent the electronic band gap where no electronic energy states exists. Electron donating impurities create electronic states near the conduction band while electron accepting impurities create electronic states near the valence band. Thus, the valance and conduction bands associated with the p-type layer 102 are higher in electronic energy than the valance and conduction bands associated with n-type layer 104.

The photovoltaic cell 100 is configured so that incident light, shown in FIG. 1A, can penetrate the layers 102, 104, and 112. As shown in FIG. 1B, when the incidnet photons have energies satisfying the condition:

hu≧E_{g}

where h is Plank's constant and u is the frequency of the photon, the photons are absorbed and electrons, denoted by “e,” are excited from the valance band into the conduction band creating electron-hole pairs, such as electron-hole pair 120. The force of the electric field across the depletion region 112 drives electrons in the conduction bands of the layers 102, 104, and 112 through the top electrode 108 to power the load 110. The electrons then pass through the bottom electrode 106 until the electrons reach the p-type layer 102 where they recombine with holes.

### Embodiments of the Present Invention

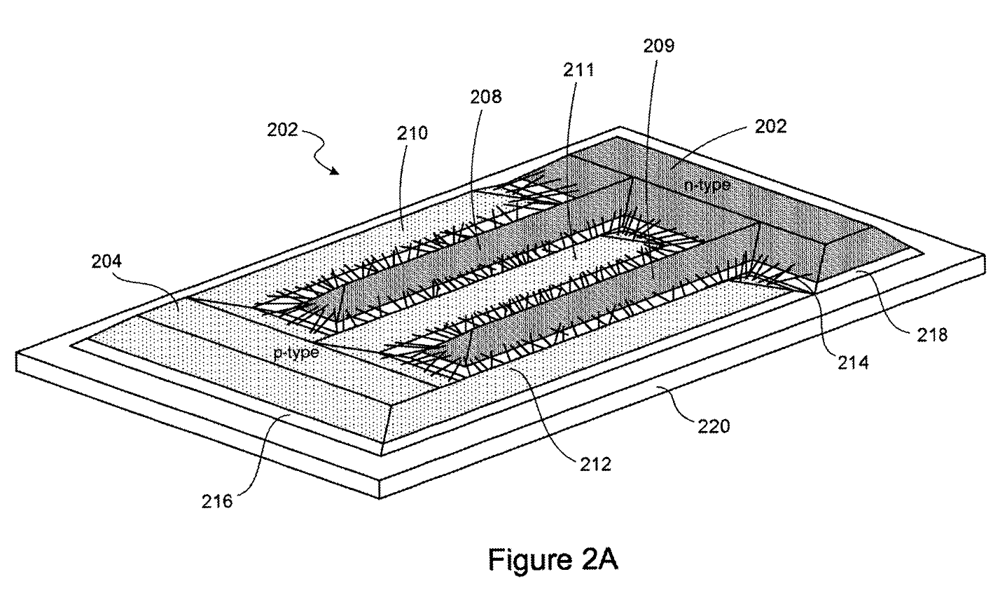

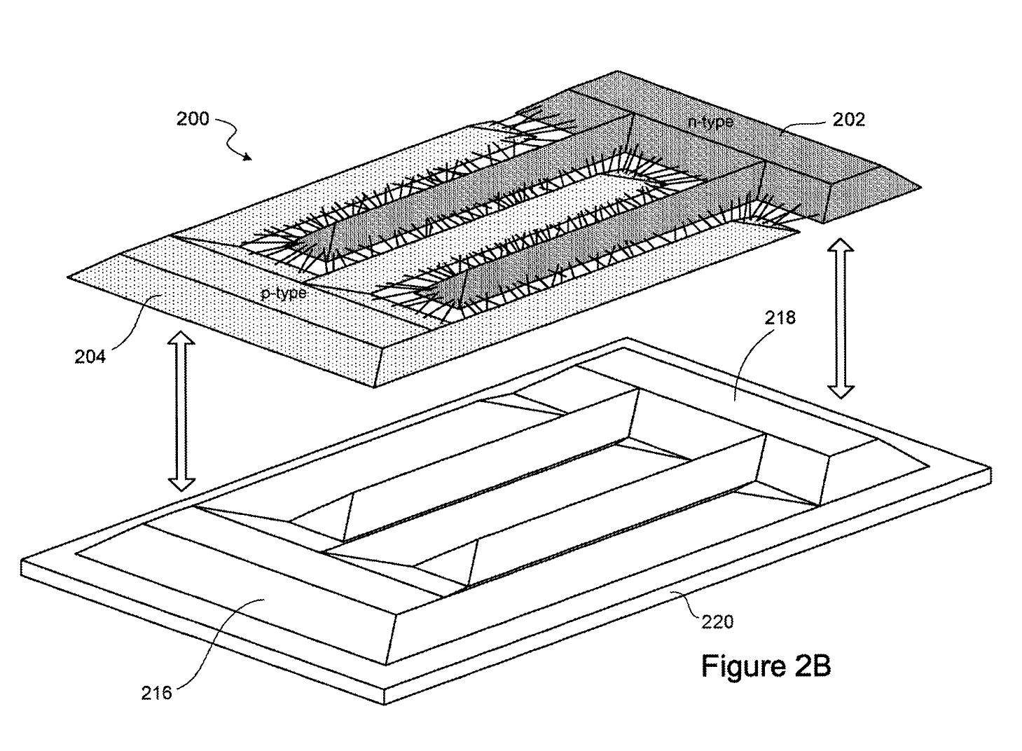

FIG. 2A shows an isometric view of a photovoltaic cell 200 configured in accordance with embodiments of the present invention. The cell 200 includes an n-type semiconductor layer 202 and a p-type semiconductor layer 204. The n-type layer 202 includes finger-like projections 208 and 209 that interleave with the finger-like projections 210-212 of the p-type layer 204. The cell 200 also includes a number of intrinsic semiconductor nanowires that electrically couple the n- and p-type layers 202 and 204. For example, nanowire 214 has a first end electrically coupled to the n-type layer 202 and a second end electrically couple to the p-type layer 204. The n-type layer 202 and the p-type layer 204 are configured with angled surfaces that enable a high concentration of nanowires to electrically couple the n-type layer 202 with the p-type layer 204. The n-type layer 202 connected to the p-type layer 204 via intrinsic nanowires forms a p-i-n junction photovoltaic cell 200.

The n-type layer 202 and the p-type layer 204 are supported by raised surfaces 216 and 218 of a substrate 220. As shown in FIG. 2A, the n-type layer 202 and the p-type layer 204 only cover the upper portions of the raises surface 216 and 218. FIG. 2B shows an exploded isometric view of the n-type layer and the p-type layer separated from the substrate 220 in accordance with embodiments of the present invention. FIG. 2B reveals the raised surfaces 216 and 218 protruding from the top surface of the substrate 220.

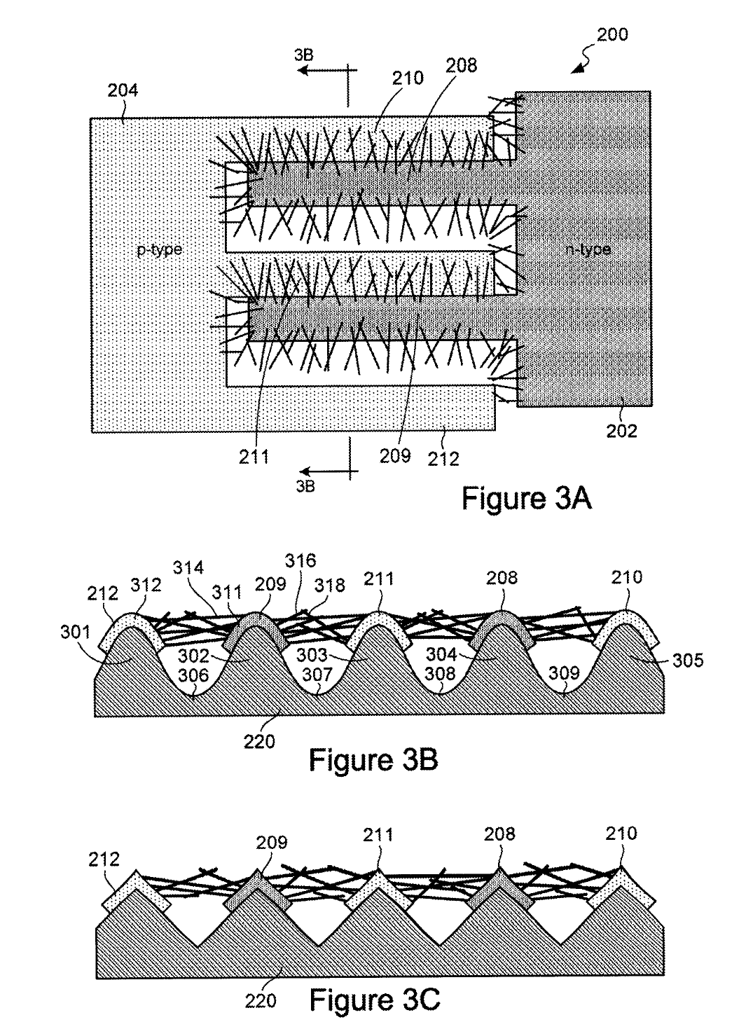

FIG. 3A shows a top view of the photovoltaic cell 200 configured in accordance with embodiments of the present invention. FIG. 3A reveals the separation between the n-type layer 202 projections 208 and 209 and the p-type layer 204 projections 210-212. In other words, no portion of the n-type layer 202 is in direct contact with the p-type layer 204. The intrinsic nanowires electrically connecting the n-type layer 202 to the p-type layer 204 forms a depletion region comprising the nanowires and neighboring portions of the n-type layer 202 and the p-type 204. The depletion region is formed by electrons diffusing from the n-type layer 202 and the nanowires into neighboring portions of the p-type region 204 and holes diffusing from the p-type layer 204 and the nanowires into neighboring portions of the n-type layer 202. The extent to which the depletion region extends into the n-type layer 202 and the p-type layer 204 depends on the strength of the electric field created across the depletion region. The electric field runs the length of the depletion region and causes electrons to drift back to toward the n-type layer 202 and holes to drift back toward the p-type layer 204. As shown in FIG. 3A, the interleaving projections 208-212 create a long depletion region, and therefore, a large number of electrons can be driven through the nanowires into the n-type layer 202 by the depletion region electric field when incident light of an appropriate frequency excites electrons into the conduction bands of the nanowires and the n- and p-type layers 202 and 204.

FIG. 3B shows a cross-sectional view of the photovoltaic cell 200 along a line 3B-3B, shown in FIG. 3A, configured in accordance with a first embodiment of the present invention. The substrate 220 has a sinusoidal pattern of raised portions 301-305 alternating with troughs 306-309. FIG. 3A reveals that each of the projections 208-212 covers at least a portion of the downward curved top surface of each raised portion 301-305. As a result, each projection has a positively sloped surface substantially facing a negatively sloped surface of a neighboring projection. For example, the projection 209 has a positively sloped surface 311 substantially facing the negatively sloped surface 312 of the neighboring projection 212. Growing nanowires on oppositely sloped surfaces of two neighboring projections increases the number of nanowires directly connecting the two surfaces, and increases the number of intersecting nanowires connecting the two surfaces. In other words, growing nanowires on oppositely sloped surfaces of two neighboring projections reduces the number of nanowires projecting from one of the surfaces that do not reach, or intersect another nanowire projecting from, the neighboring surface. For example, the nanowire 314 electrically connects the projection 212 and the projection 209, and the two intersecting nanowires 316 and 318 electrically connect the projection 209 and the projection 211. FIG. 3C shows a cross-sectional view of the photovoltaic cell 200 along a line 3B-3B, shown in FIG. 3A, configured with a saw-tooth cross-section in accordance with embodiment of the present invention.

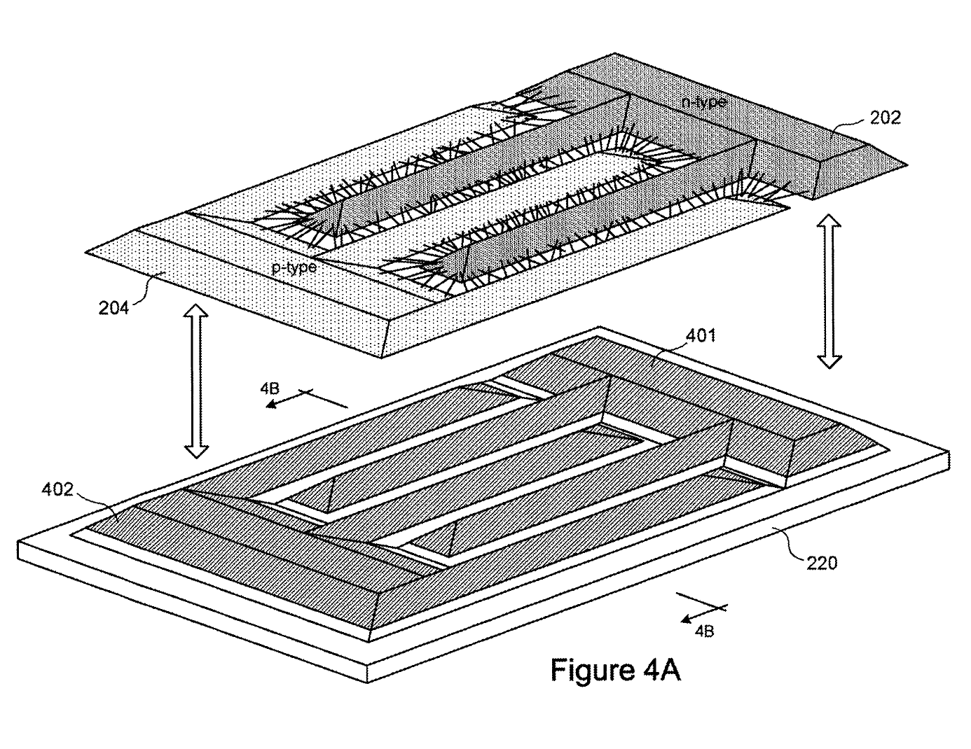

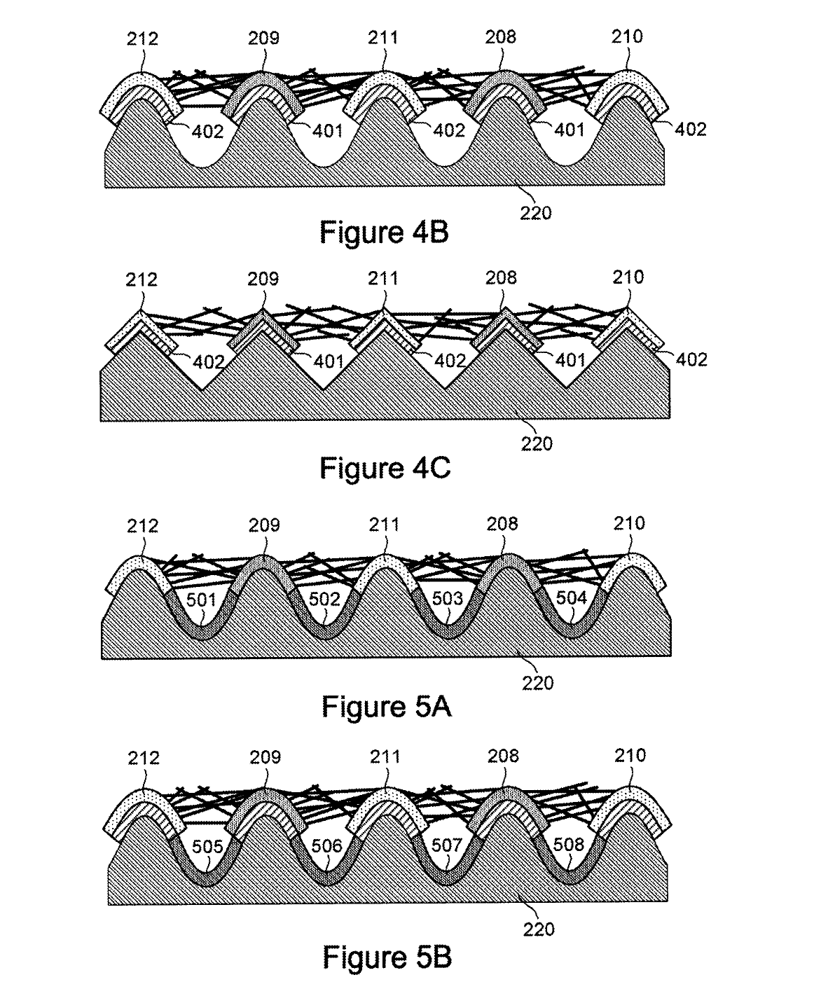

In certain embodiments, a first electrode can be electrically coupled to the top surface of the n-type layer 202 and a second electrode can be electrically coupled to the top surface of the p-type layer 204, where the first and second electrodes are electrically coupled to load (not shown). In other embodiments, in order to maximize the surface area of the n- and p-type layers 202 and 204 exposed to incident light, electrodes connected to a load can be disposed between the n- and p-type layers 202 and 204 and the substrate 220. FIG. 4A shows an exploded isometric view of a photovoltaic cell 400 configured in accordance with embodiments of the present invention. The photovoltaic cell 400 includes a first electrode 401 disposed between the n-type layer 202 and the substrate 220 and a second electrode 402 disposed between the p-type layer 204 and the substrate 220. FIG. 4B shows a cross-sectional view of the photovoltaic cell 400 along the 4B-4B, shown in FIG. 4A, configured with a sinusoidal cross-section in accordance with a embodiment of the present invention. The first electrode 401 is disposed between the projections 208 and 209 and the substrate 220, and the second electrode 402 is disposed between the projections 210-212 and the substrate 220. FIG. 4C shows a cross-sectional view of the photovoltaic cell 400 along a line 4B-4B, shown in FIG. 4A, configured with a saw-tooth cross-section in accordance with a second embodiment of the present invention.

In certain embodiments, a reflective layer can be disposed on the surface of the substrate grooves between the n- and p-type layers and beneath the nanowires. FIG. 5A shows a cross-sectional view of reflective layers 501-504 disposed on the substrate grooves between the projections of the n- and p-type layers of the photovoltaic cell 200 configured in accordance with embodiments of the present invention. FIG. 5B shows a cross-sectional view of reflective layers 505-508 disposed on the substrate grooves between the projections of the n- and p-type layers of the photovoltaic cell 400 configured in accordance with embodiments of the present invention. The reflective layers 501-508 reflect incident light that passes between the nanowires back onto to the nanowires and thereby increases the amount of incident light converted into electrical energy. In certain embodiments, the reflective layers 501-508 can be composed of SiO₂, Si₃N₄, or another suitable reflective dielectric material. In other embodiments, the reflective layers can be composed of a reflective metallic material, such as silver or aluminum. Note that when metallic reflective layers are selected, gaps (not shown) need to be included between the reflective layers 501-504 and the n- and p-type projections of the photovoltaic cell 200 shown in FIG. 5A, and gaps (not shown) needed to be included between the reflective layers 505-508 and the first and second electrodes of the photovoltaic cell 400 shown in FIG. 5B.

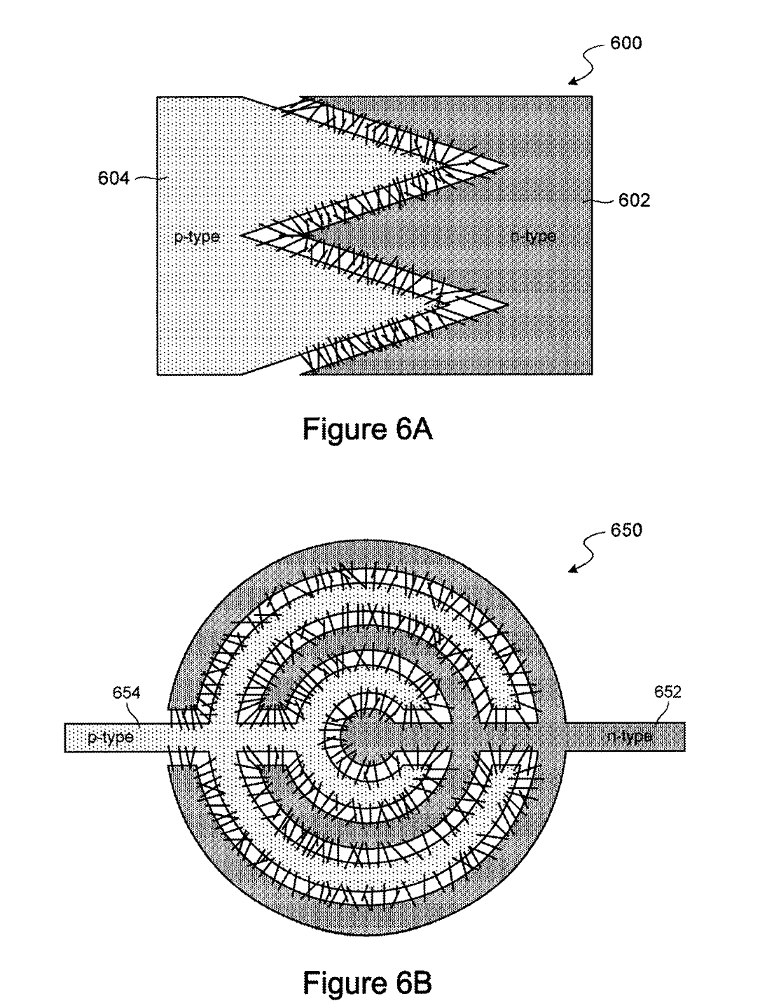

Photovoltaic cells can have any number of different shapes and a number of different depletion region configurations. FIG. 6A shows a top-view of photovoltaic cell 600 configured in accordance with embodiments of the present invention. The cell 600 is rectangularly shaped and includes an n-type layer 602 and a p-type layer 604, but in contrast to the rectangular-shaped projections 208-212 of the photovoltaic cell 200, saw-tooth shaped projections are employed to form the depletion region and the n- and p-type layers 602 and 604. FIG. 6B shows a top-view of a photovoltaic cell 650 configured in accordance with embodiments of the present invention. The cell 650 is circular-shaped and includes an n-type layer 652 and p-type layer 654. The n-type layer 652 and the p-type layer 654 include interleaving semi-circular projections extending from central axes.

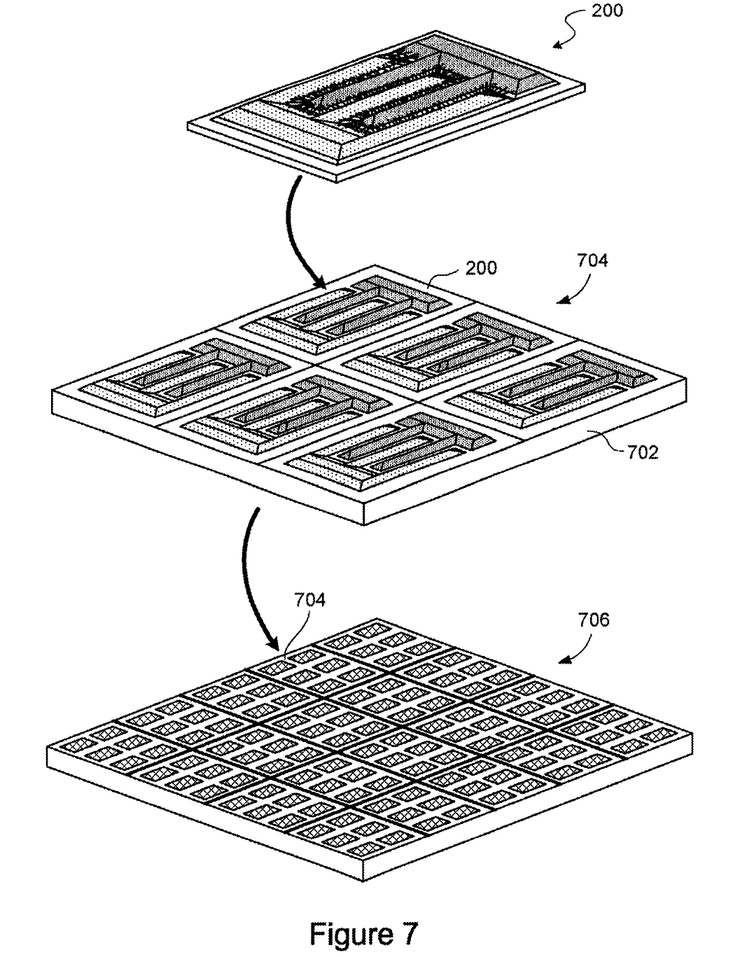

The photovoltaic cells of the present invention can be arrayed to form photovoltaic modules, which, in turn, can be electrically connected to form photovoltaic panels. FIG. 7 shows combining photovoltaic cells to produce a photovoltaic panel in accordance with embodiments of the present invention. In FIG. 7, six nearly identical photovoltaic cells 200 are electrically connected and packaged in a support structure or frame 702 to form a photovoltaic module 704. Photovoltaic modules of the present invention are not limited to six photovoltaic cells, but can be fabricated with any suitable number of cells to produce a desired voltage level. FIG. 7 also shows twenty photovoltaic modules electrically connected in series or parallel to form a photovoltaic panel 706. Photovoltaic panel embodiments are not limit to the number and arrangement of modules of the photovoltaic panel 706. The number and arrangement of modules can vary depending on use and the amount of electrical power desired.

The n-type and p-type layers of the photovoltaic cells described above can be composed of indirect band gap semiconductors and direct band gap compound semiconductors depending on costs, efficiency, and/or the range of wavelengths of incident light to be converted into electrical power. For example, in order to employ the photovoltaic cell embodiments in low cost solar panels, the n-type and p-type layers can be amorphous or crystalline silicon, where the n-type layer can be doped with electron donating impurities, such as nitrogen, phosphorous, and selenium, and the p-type layer can be doped with electron accepting impurities, such as boron, aluminum, gallium, and indium. In other embodiments, direct band gap compound semiconductors can be used. Compound semiconductors are typically III-V materials, where Roman numerals III and V represent elements in the IlIa and Va columns of the Periodic Table of the Elements as displayed in Table I:

TABLE I

| IIIa | Va |
|---|---|
| Aluminum (“Al”) | Nitrogen (“N”) |
| Gallium (“Ga”) | Phosphorus (“P”) |
| Indium (“In”) | Arsenic (“As”) |
| | Antimony (“Sb”) |

Compound semiconductors can be classified according the quantities of III and V elements comprising the semiconductor. For example, binary semiconductor compounds include GaAs, InP, InAs, and GaP; ternary semiconductor compounds include GaAs_{y}P_{1-y}, where y ranges between 0 and 1; and quaternary semiconductor compounds include InₓGa₁₋ₓAs_{y}P_{1-y}, where both x and y range between 0 and 1. Other types of suitable compound semiconductors include Il-VI materials, where II and VI represent elements in the IIb and Via columns of the periodic table. For example, CdSe, ZnSe, ZnS, and ZnO are examples of suitable binary II-VI compound semiconductors.

The nanowires can be composed of intrinsic indirect band gap semiconductors, such as silicon and germanium, or intrinsic direct band gap semiconductor materials. The substrate 220 can be composed of SiO₂, Si₃N₄, or another suitable insulating material. The electrode disposed between the n-type layer and the substrate 220 and the electrode disposed between the p-type layer and the substrate 220, as shown in FIG. 4, can be composed of silver, gold, copper, aluminum, stainless steel, or another suitable conductive material.

The photovoltaic cells have a number of advantages over conventional photovoltaic cells. First, in conventional photovoltaic cells, the n- and p-type layers comprising the light absorbing material are stacked and incident light has to penetrate deep into the light absorbing material to initiate electron-hole pair formation. In contrast, the n-type layer, the p-type layer, and the intrinsic nanowires of the photovoltaic cell embodiments of the present invention are exposed directly to the incident light. In other words, the p-i-n junction layers of photovoltaic cells of the present invention receive the full amount of the incident light. Second, in conventional photovoltaic cells, one of the two electrodes typically covers at least a portion of the surface of the light absorbing material exposed to the incident light. As a result, the full amount of light incident upon the photovoltaic cell is not able to reach the light absorbing material underneath. In contrast, photovoltaic cells of the present invention can be configured with the electrodes disposed between the substrate 220 and the n-type and the p-type layers, as shown in FIG. 4, and therefore, the full amount of incident light again reaches the p-i-n junction layers without being blocked by the electrodes. Third, the grooves between the n- and p-type layers are reflectors that reflect light penetrating between the nanowire on a first pass back onto the nanowires. The grooves can be concave shaped as shown in the cross-sectional views of FIGS. 3-5 and thereby serve as concentrators to increase the light intensity at the nanowires to greater than just incident photons. The bottom layer can be thought of as a concave metallic mirror that redirects light to the nanowires.

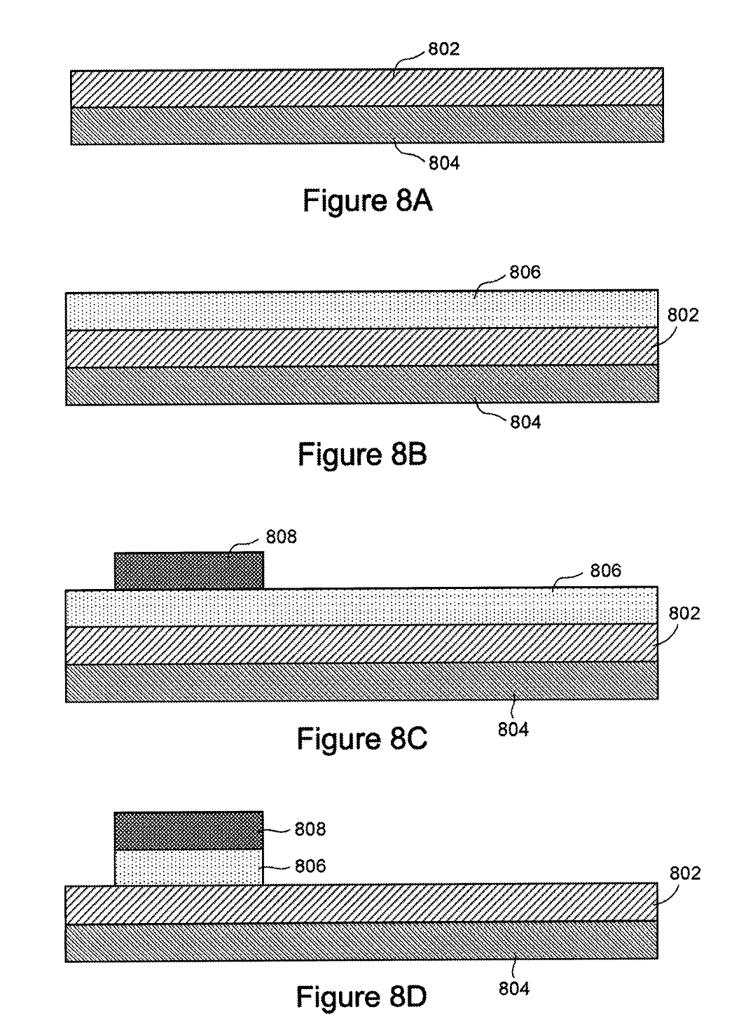

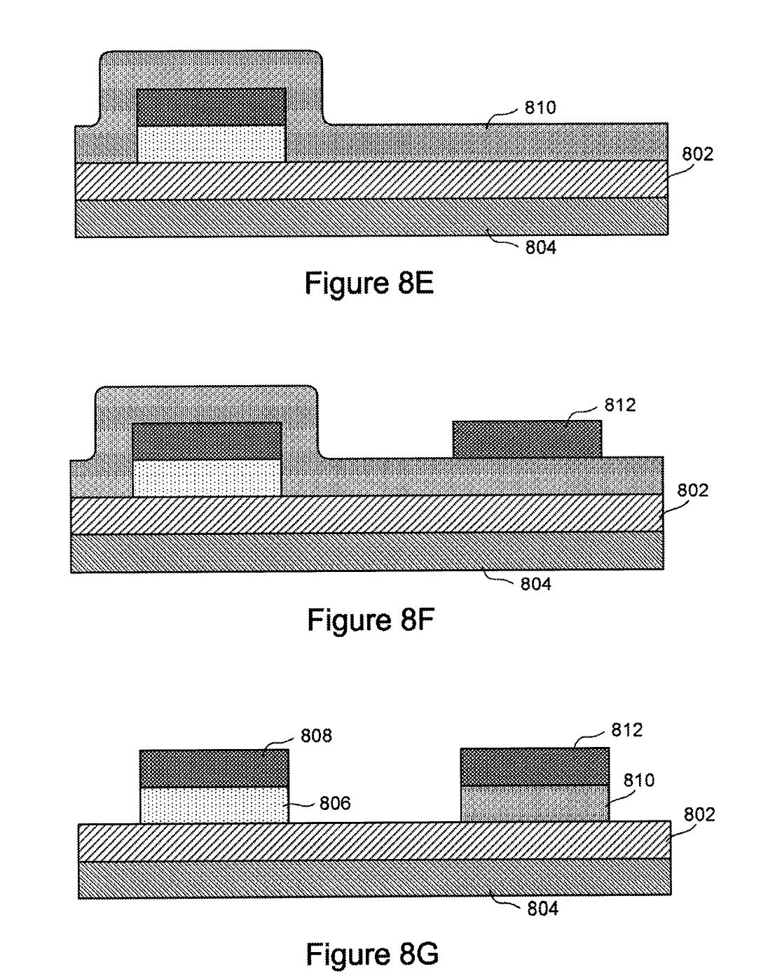

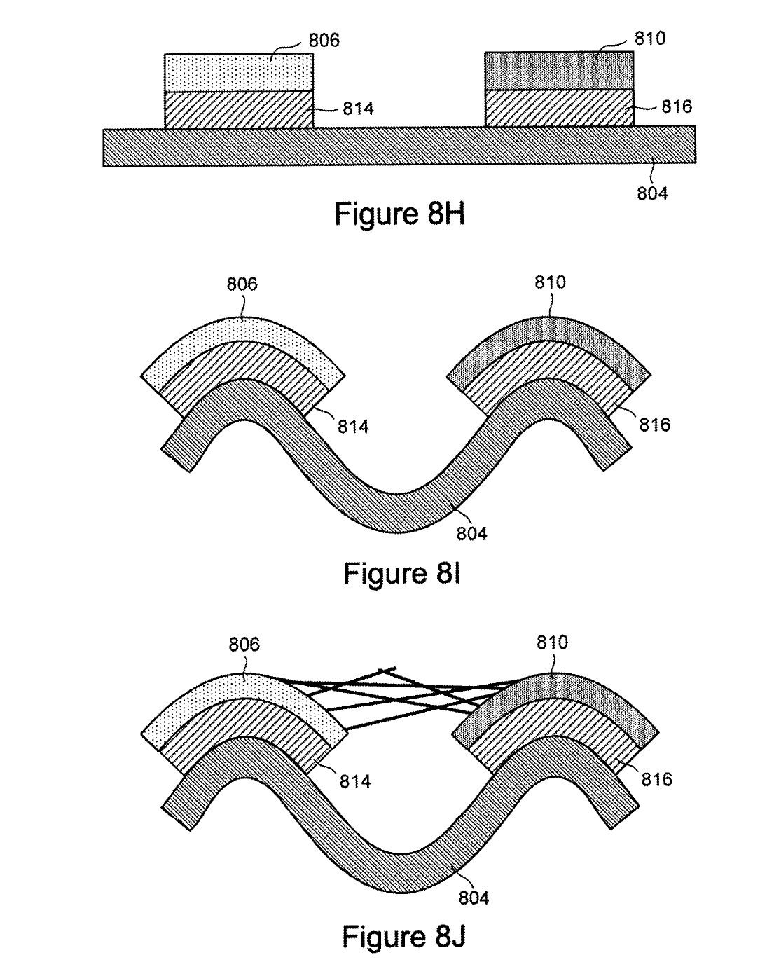

FIGS. 8A-8J show cross-sectional views of steps comprising a method for fabricating the photovoltaic cells, shown in FIG. 4, in accordance with embodiments of the present invention. Initially, as shown in FIG. 8A, an electrically conductive layer 802 is deposited on a substrate 804 using evaporation, sputtering, atom layer deposition (“ALD”), or wafer bonding. The layer 802 can be silver, gold, aluminum, copper, stainless steel, or another suitable conductive material, and the substrate 804 can be SiO₂, Si₃N₄, or another suitable dielectric material

Next, as shown in FIG. 8B, a first semiconductor layer 806 is deposited on the electrically conductive layer 802 using plasma-enhanced chemical vapor deposition (“PECVD”) or wafer bonding. The first semiconductr layer 806 can be amorphous silicon, crystalline silicon, or a compound semiconductor. The first semiconductor layer 806 can be doped with an electron accepting impurity by introducing a p-type impurity to the reaction chamber while the first semiconductor layer 806 is forming. Alternatively, a p-type impurity can be added to an already formed first semiconductor layer 806 using dopant diffusion or implantation followed by annealing.

Next, as shown in FIG. 8C, a resist is deposited on the first semiconductor layer 806 using chemical vapor deposition (“CVD”) or wafer bonding and patterned to correspond to a p-type layer, such as the p-type layers shown in FIGS. 3A, 5, and 6, using electron beam lithography (“EBL”), x-ray lithography, photolithography, focused ion beam lithography, extreme UV lithography (“EUVL”), or nanoimprint lithography (“NIL”). Next, as shown in FIG. 8D, the resist pattern is formed in the first semiconductor layer 806 using reactive ion etching (“RIE”) or focused ion beam milling (“FIM”).

Next, as shown in FIG. 8E, a second semiconductor layer 810 is deposited using PECVD. The second semiconductor layer 810 can be amorphous silicon, crystalline silicon, or a compound semiconductor and can be doped by introducing an n-type impurity to the reaction chamber while the second semiconductor layer 810 is forming. Alternatively, an n-type impurity can be added to an already formed second semiconductor layer 810 using dopant diffusion or implantation followed by annealing.

Next, as shown in FIG. 8F, a resist 808 is deposited using CVD on the second semiconductor layer 810 and patterned to correspond to an n-type layer, such as the n-type layers shown in FIGS. 3A, 5, and 6, using EBL, x-ray lithography, photolithography, focused ion beam lithography, EUVL, or NIL. As shown in FIG. 8G, the pattern of the resist 812 is formed in the second semiconductor layer 810 using RIE or FIM.

Next, as shown in FIG. 8H, the exposed electrically conductive material 802 not covered by the n-type and p-type layers is removed using RIE or FIM leaving separate electrodes 814 and 816, and planarization techniques can be used remove the resists 808 and 812.

Next, as shown in FIG. 81, the substrate 804 and n- and p-type layers are pressed against a mold having sinusoidal configuration that raises the regions beneath the n-type layer 806 and the p-type layer 810 creating sloped surfaces along the n-type layer and the p-type layer.

Finally, as shown in FIG. 8J, nanwires are grown. First, seed particles are deposited on the sloped surfaces of the n-type layer 806 and the p-type 810 layer using galvanic displacement. The seed particles can be gold, titanium, nickel, chromium, platinum, palladium, aluminum, or another suitable metal conductor or metal alloy. Next, using CVD, nanowires are grown in accordance with well-known vapor-liquid-solid (“VLS”) growth mechanism or vapor-solid-solid (“VSS”) growth mechanism. Continued supply of the vapor-phase reactants forming the nanowires results in supersaturation, which eventually causes precipitation of excess liquid-phase material forming the nanowires beneath the seed particles.

In other fabrication embodiments, the grooved surface of the substrate can be formed by embossing a thin metal foil on the substrate with an embrosser having a complimentary surface. Using various methods of deposition, shadow masking deposition methods and/or spray on methods, such as inkjet, the cystalline p- and n-type layers can be deposited.

The foregoing description, for purposes of explanation, used specific nomenclature to provide a thorough understanding of the invention. However, it will be apparent to one skilled in the art that the specific details are not required in order to practice the invention. The foregoing descriptions of specific embodiments of the present invention are presented for purposes of illustration and description. They are not intended to be exhaustive of or to limit the invention to the precise forms disclosed. Obviously, many modifications and variations are possible in view of the above teachings. The embodiments are shown and described in order to best explain the principles of the invention and its practical applications, to thereby enable others skilled in the art to best utilize the invention and various embodiments with various modifications as are suited to the particular use contemplated. It is intended that the scope of the invention be defined by the following claims and their equivalents:

1. A photovoltaic cell comprising:
a first semiconductor layer doped with a first impurity and disposed on a portion of a first raised surface of a substrate, the first semiconductor layer having at least one negatively sloped surface;
a second semiconductor layer doped with a second impurity and disposed on a second raised surface of the substrate, the second semiconductor layer having at least one positively sloped surface neighboring the at least one negatively sloped surface of the first semiconductor; and
at least one nanowire electronically coupled to the negatively sloped surface of the first semiconductor layer and electronically coupled to the positively sloped surface of the second semiconductor layer.

2. The photovoltaic cell of claim 1 wherein the substrate further comprises a groove separating the first and second raised surfaces.

3. The photovoltaic cell of claim 1 further comprises:
a first electrode disposed between the first semiconductor layer and the first raised surface of the substrate; and
a second electrode disposed between the second semiconductor layer and the second raised surface of the substrate.

4. The photovoltaic cell of claim 3 wherein the first electrode and the second electrode further comprise one of:
stainless steal;
silver;
gold;
copper;
aluminum; and
another suitable conductor.

5. The photovoltaic cell of claim 1 wherein the substrate further comprise one of:
SiO₂;
Si₃N₄; and
another suitable insulating material.

6. The photovoltaic cell of claim 1 wherein the at least one nanowire further comprises an intrinsic semiconductor.

7. The photovoltaic cell of claim 1 wherein the at least one nanowire further comprises one of:
amorphous silicon;
crystalline silicon;
germanium;
a III-V semiconductor; and
a II-VI semiconductor.

8. The photovoltaic cell of claim 1 wherein the first and second semiconductor layers further comprises one of:
amorphous silicon;
crystalline silicon;
a III-V semiconductor;
a II-VI semiconductor;
a polymer semiconductor; and
a suitable light absorbing material.

9. The photovoltaic cell of claim 1 wherein the first impurity and the second impurity further comprise electron donating impurities and electron accepting impurities.

10. The photovoltaic cell of claim 1 further comprises a reflective layer disposed on the substrate between the first and second semiconductors and beneath the nanowires.

11. A method for fabricating a photovoltaic cell, the method comprising:
depositing an electrically conductive layer on a first surface of a substrate;
forming a first portion of the photovoltaic cell on the electronically conductive layer, the first portion comprising a semiconductor doped with a first impurity;
forming a second portion of the photovoltaic cell on the electronically conductive layer, the second portion comprising a semiconductor doped with a second impurity;
forming at least one angled surface in the first portion of the photovoltaic cell and at least one angled surface in the second portion of the photovoltaic cell; and
growing at least one nanowire, the nanowire electronically coupled to the angled surface of the first portion of the photovoltaic cell and electronically coupled to the angled surface of the second portion of the photovoltaic cell.

12. The method of claim 10 wherein forming the first portion of the photovoltaic cell on the electronically conductive layer further comprises
depositing a first semiconductor layer doped with the first impurity on the electronically conductive layer; and
etching the first semiconductor layer to form the first portion of the photovoltaic cell.

13. The method of claim 11 wherein depositing the first semiconductor layer further comprises employing plasma enhanced chemical vapor deposition.

14. The method of claim 11 wherein etching the first semiconductor layer to form the first portion of the photovoltaic cell further comprises employing reactive ion etching.

15. The method of claim 10 wherein forming the second portion of the photovoltaic cell on the electronically conductive layer further comprises
depositing a second semiconductor layer doped with the second impurity on the electronically conductive layer; and
etching the second semiconductor layer to form the second portion of the photovoltaic cell.

16. The method of claim 11 wherein depositing the first semiconductor layer further comprises employing plasma enhanced chemical vapor deposition.

17. The method of claim 11 wherein etching the first semiconductor layer to form the first portion of the photovoltaic cell further comprises employing reactive ion etching.

18. The method of claim 10 further comprises forming electrodes between the first and second portions of the photovoltaic cells and the substrate by removing portions of the electronically conductive layer that are not covered by the first and second portions of the photovoltaic cells.

19. The method of claim 10 forming the at least one angled surface of the first portion of the photovoltaic cell and the at least one angled surface of the second portion of the photovoltaic cell further comprises pressing the substrate beneath the first and second portions of the photovoltaic cell against a mold that raises at least a portion of the first portion of the photovoltaic cell to form the at least one angled surface and the at least one angled surface of the second portion of the photovoltaic cell.

20. The method of claim 10 wherein growing the at least one nanowire further comprises employing vapor-liquid-solid chemical synthesis process.
